(19) United States
(12) Patent Application Publication
(10) Pub. No.: US 2026/0147946 A1
(43) Pub. Date: May 28, 2026

(54) SIMULATION DEVICE, SIMULATION METHOD, AND STORAGE MEDIUM

(71) Applicant: DENSO CORPORATION, Kariya-city (JP)

(72) Inventor: Tomihiro IKEGAMI, Kariya-city (JP)

(21) Appl. No.: 19/446,511

(22) Filed: Jan. 12, 2026

Related U.S. Application Data
(63) Continuation of application No. PCT/JP2024/024439, filed on Jul. 5, 2024.

(30) Foreign Application Priority Data
Jul. 14, 2023 (JP) 2023-116002

(51) Int. Cl. G06F 30/10

(52) U.S. Cl. CPC G06F 30/10

(57) ABSTRACT

A Simulation device includes a polygon identification unit and a collision position correction unit. The polygon identification unit is configured to identify a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface. The collision position correction unit is configured to calculate a collision point where the wave collides with based on a target surface, the target surface is a surface calculated by performing a surface interpolation on the plane of the target polygon.

### CROSS-REFERENCE TO RELATED APPLICATIONS

The present application is a continuation application of International Application No. PCT/JP2024/024439 filed on Jul. 5, 2024, which claims priority to Japanese Application No. 2023-116002, filed on Jul. 14, 2023. The contents of these applications are incorporated herein by reference in their entirety.

### BACKGROUND

### 1. Technical Field

This disclosure relates to a simulation device, a simulation method, and a storage medium for forming waves through simulation.

### 2. Related Art

JP2017004516A describes a method for a computer graphics system to perform tessellation. Tessellation is a technique for further subdividing many polygons (e.g., triangular polygons) used to represent a three-dimensional solid.

### SUMMARY

An embodiment of the present disclosure is a simulation device comprising a polygon identification unit and a collision position correction unit.

The polygon identification unit is configured to identify a target polygon among multiple polygons. The target polygon is a polygon with which a wave formed by simulation collides. Each of the multiple polygons has vertices. Each of the vertices is a point of a three-dimensional coordinate point cloud representing a three-dimensional shape of an object surface.

The collision position correction unit is configured to calculate a collision point where the wave collides with based on a target surface, the target surface is a surface calculated by performing a surface interpolation on the plane of the target polygon.

According to the simulation device of the present disclosure, it is possible to improve a reproduction accuracy in simulations, because it can minimize the difference between the position where the wave collides with on a real object and the position where the wave collides with the object reproduced in the simulation.

Another aspect of the present disclosure relates to a simulation method performed by a simulation device. The simulation method comprises: identifying a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface, and calculating a collision point where the wave collides with based on a target surface, the target surface is a surface calculated by performing a surface interpolation on the plane of the target polygon.

The simulation method of the present disclosure is a method performed by the simulation device of the present disclosure. Performing this method enables the achievement of effects similar to those of the simulation device of the present disclosure.

Another aspect of the present disclosure is a non-transitory computer-readable storage medium storing a simulation program for causing a computer to function as a polygon identification unit and a collision position correction unit.

A computer controlled by the simulation program of the present disclosure may constitute a part of the simulation device of the present disclosure and can achieve effects similar to those of the simulation device of the present disclosure.

### BRIEF DESCRIPTION OF THE DRAWING

FIG. 1 is a block diagram showing a configuration of the radar simulator.

FIG. 2 is a flowchart showing a collision position correction process.

FIG. 3 is a diagram showing setting and movement of control points.

FIG. 4 is a diagram showing collision points on a polygon and collision points on a Bezier surface.

### DETAILED DESCRIPTION OF THE PREFERRED EMBODIMENTS

In recent years, an expansion of advanced safety functions in vehicles has been progressing. To improve development process efficiency, in addition to performance verification using test vehicles, the frequency of performance verification by reproducing driving environments through computer simulation is increasing. There is a demand for improving the accuracy of performance verification using computer simulation.

Advanced safety functions are realized using external environment recognition sensors to perceive the environment outside the vehicle. These external environment recognition sensors include both active sensors and passive sensors. Examples of active sensors include radar devices, sonar, and LiDAR. Cameras are an example of a passive sensor.

Each of the active sensors transmits radio waves, ultrasonic waves, or light (electromagnetic waves), and recognize external objects by receiving the reflected electromagnetic wave and generating electrical power (received power).

The computer simulator described above calculates the electrical power generated when the radio waves, ultrasonic waves, or light transmitted by the sensor collide with objects such as people, vehicles, and roads present around the vehicle.

Particularly when calculating power generated by radio waves or ultrasonic waves, it is important to accurately calculate not only the magnitude of the power but also the phase (i.e., the temporal shift of the power wave).

Regarding the phase, for example, when two electromagnetic waves are received simultaneously, when they are in the same phase, the power is amplified, and when they are in the opposite phase, the power is canceled out and disappears.

The phase varies both at the moment of the reflection at a surface of an object surface and when the wave propagates through space. Accurately reproducing phase variations during wave propagation through space requires the shape of the object to be precisely represented. For millimeter-wave radar, where wavelengths are on the order of several millimeters, even a 1 mm shift in propagation distance causes significant errors in the received power.

In computer simulations, the shape of an object is often represented by connecting polygons. However, for curved objects, it is impossible to make the polygons perfectly match the ideal shape.

As a result of detailed examination by the inventors, it was discovered that the phase of electromagnetic waves colliding with an object can differ between reality and simulation, potentially causing significant errors in the calculation of received power in the simulation.

This disclosure improves a reproduction accuracy in simulations.

An embodiment of the present disclosure is a simulation device comprising a polygon identification unit and a collision position correction unit.

The polygon identification unit is configured to identify a target polygon among multiple polygons. The target polygon is a polygon with which a wave formed by simulation collides. Each of the multiple polygons has vertices. Each of the vertices is a point of a three-dimensional coordinate point cloud representing a three-dimensional shape of an object surface.

The collision position correction unit is configured to calculate a collision point where the wave collides with based on a target surface, the target surface is a surface calculated by performing a surface interpolation on the plane of the target polygon.

According to the simulation device of the present disclosure, it is possible to improve a reproduction accuracy in simulations, because it can minimize the difference between the position where the wave collides with on a real object and the position where the wave collides with the object reproduced in the simulation.

Another aspect of the present disclosure relates to a simulation method performed by a simulation device. The simulation method comprises: identifying a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface, and calculating a collision point where the wave collides with based on a target surface, the target surface is a surface calculated by performing a surface interpolation on the plane of the target polygon.

The simulation method of the present disclosure is a method performed by the simulation device of the present disclosure. Performing this method enables the achievement of effects similar to those of the simulation device of the present disclosure.

Another aspect of the present disclosure is a non-transitory computer-readable storage medium storing a simulation program for causing a computer to function as a polygon identification unit and a collision position correction unit.

A computer controlled by the simulation program of the present disclosure may constitute a part of the simulation device of the present disclosure and can achieve effects similar to those of the simulation device of the present disclosure. The embodiments of the present disclosure are described below with reference to the drawings.

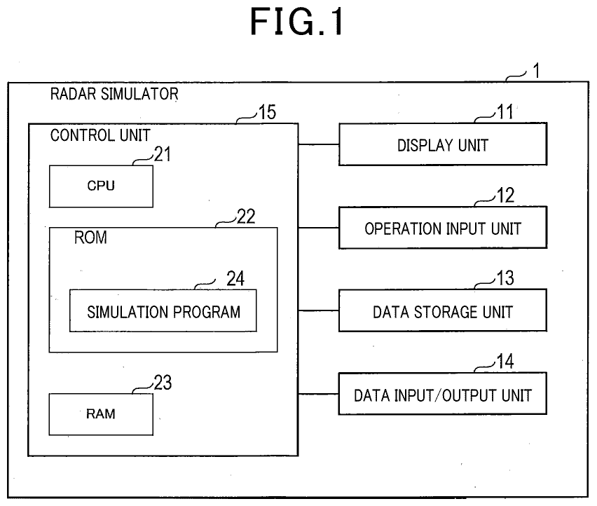

As shown in FIG. 1, a radar simulator 1 according to an embodiment is provided with a display unit 11, an operation input unit 12, a data storage unit 13, a data input/output unit 14, and a control unit 15.

The display unit 11 includes a display (not shown) and displays various images on the display screen.

The operation input unit 12 outputs input operation information to identify input operations performed by a user via a keyboard or mouse (not shown).

The data storage unit 13 is a storage device for storing various data.

The data input/output unit 14 performs data input/output with external devices connected via a cable or a wireless network.

The control unit 15 is primarily configured by a microcomputer including a CPU 21, ROM 22, and RAM 23, among others. The various functions of the microcomputer are realized by the CPU 21 executing programs stored on a non-transitory physical storage medium. The ROM 22 is an example of such a non-transitory physical storage medium storing programs. Execution of the program causes the corresponding method to be performed. At least one of the functions executed by the CPU 21 may be implemented using one or more hardware components, such as ICs. The number of microcomputers constituting the control unit 15 may be one or more.

The ROM 22 stores a simulation program 24. The simulation program 24 may be pre-installed in radar simulator 1 or may be installed via a recording medium or a network. Examples of recording media include optical disks, magnetic disks, and semiconductor memory.

The simulation program 24 is configured to reproduce a three-dimensional shape of roads and their surroundings in a virtual space using high-precision three-dimensional map data, and to drive a vehicle on the roads reproduced in the virtual space.

In this embodiment, the three-dimensional map data is a three-dimensional coordinate point cloud that represents the three-dimensional shape of an object surface by a set of coordinate points expressed in the three-dimensional coordinates. The simulation program 24 is configured to reproduce the three-dimensional shape in the virtual space by generating a large number of polygons (triangular polygons in this embodiment) with each of the multiple three-dimensional coordinate points constituting the three-dimensional coordinate point cloud as a vertex.

Furthermore, the simulation program 24 is configured to simulate the transmission and reception of radar waves by a radar device mounted to the vehicle traveling in the virtual space.

By launching the simulation program 24 stored in the ROM 22, a radar simulation is executed that simulates both a movement of the vehicle and the transmission and reception of the radar waves by the radar device.

Next, a collision position correction process, for correcting a collision position where the radar waves collides with objects in the radar simulation, is described.

The collision position correction process is performed each time after the transmission wave generation processing, which generates the radar wave transmitted by the radar device (hereinafter referred to as the transmission wave), is executed in the radar simulation. The transmission wave generation process is performed each time a predetermined radar wave transmission cycle elapses. The predetermined radar wave transmission cycle is set in advance for the virtual space formed by the radar simulation,.

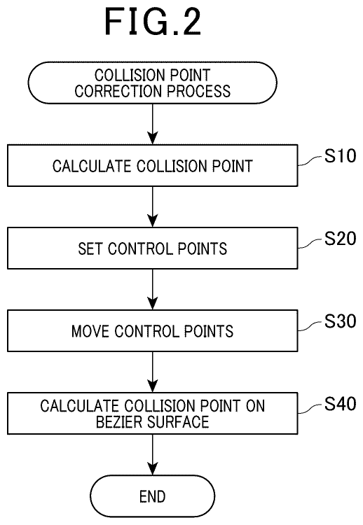

As shown in FIG. 2, when the collision position correction process is performed, in step S10, the CPU 21 of the control unit 15 calculates the collision position where the radar wave collides with a polygon. The collision position is calculated based on the propagation path of the radar wave and the positions of a set of three-dimensional coordinate points. This identifies the polygon (hereinafter referred to as the target polygon) with which the radar wave collides.

In S20, CPU 21 sets an initial position for each of control points b_{i,j,k} relative to the target polygon.

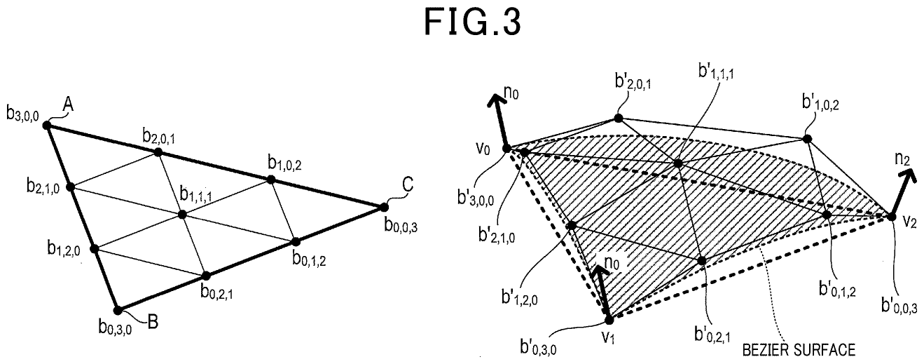

As shown in FIG. 3, the initial position of each of the control points b_{i,j,k} of the target polygon is set to each of vertexes of a triangle, each of positions that divides each edge of the triangle into three equal parts, and a center position of the triangle.

For simplicity of notation, control point bi, j, k may also be referred to as control point bi.

The b_{i, j, k} represents the control point by i, j, and k. In the case of Bezier interpolation used in this embodiment, i+j+k=3 is satisfied.

The control point bi on triangle ABC is expressed by equation (1). In equation (1), A, B, and C are vectors indicating the coordinate positions of the respective vertices A, B, and C of the triangle ABC. In this embodiment, since the degree of the Bezier surface is 3 (i.e., n=3), the control point bi on the triangle ABC is expressed by equation (2).

$$[ Math 1 ]$$

$${\vec{b}}_{\vec{ι}} = \frac{i \vec{A} + j \vec{B} + k \vec{C}}{n} \qquad ( 1 )$$

$${\vec{b}}_{\vec{ι}} = \frac{i \vec{A} + j \vec{B} + k \vec{C}}{3} \qquad ( 2 )$$

As shown in FIG. 2, in step S30, the CPU 21 generates a surface based on the target polygon. The CPU 21 moves each of the control points bi by applying vertex normal vectors n₀, n₁, n₂ to equations (3) to (12). The respective vertex normal vectors n₀, n₁, n₂ is a normal vector at three vertices constituting the target polygon. Each of control points b′i indicates a position after being moved from the control point bi using equations (3) to (12). The vectors v₀, v₁, and v₂ in equations (3) to (12) are vectors indicating the positions of the control points b_{3,0,0}, b_{0,3,0}, and b_{0,0,3} respectively.

$$[ Math 2 ]$$

$${\vec{{b}^{′}}}_{3 , 0 , 0} = {\vec{b}}_{3 , 0 , 0} \qquad ( 3 )$$

$${\vec{{b}^{′}}}_{2 , 1 , 0} = {\vec{b}}_{2 , 1 , 0} + [ {\vec{n}}_{0} \cdot ( {\vec{b}}_{2 , 1 , 0} - {\vec{v}}_{0} ) ] {\vec{n}}_{0} \qquad ( 4 )$$

$${\vec{{b}^{′}}}_{2 , 0 , 1} = {\vec{b}}_{2 , 0 , 1} + [ {\vec{n}}_{0} \cdot ( {\vec{b}}_{2 , 0 , 1} - {\vec{v}}_{0} ) ] {\vec{n}}_{0} \qquad ( 5 )$$

$${\vec{{b}^{′}}}_{1 , 2 , 0} = {\vec{b}}_{1 , 2 , 0} + [ {\vec{n}}_{1} \cdot ( {\vec{b}}_{1 , 2 , 0} - {\vec{v}}_{1} ) ] {\vec{n}}_{1} \qquad ( 6 )$$

$${\vec{{b}^{′}}}_{1 , 0 , 2} = {\vec{b}}_{1 , 0 , 2} + [ {\vec{n}}_{2} \cdot ( {\vec{b}}_{1 , 0 , 2} - {\vec{v}}_{2} ) ] {\vec{n}}_{2} \qquad ( 7 )$$

$${\vec{{b}^{′}}}_{0 , 3 , 0} = {\vec{b}}_{0 , 3 , 0} \qquad ( 8 )$$

$${\vec{{b}^{′}}}_{0 , 2 , 1} = {\vec{b}}_{0 , 2 , 1} + [ {\vec{n}}_{1} \cdot ( {\vec{b}}_{0 , 2 , 1} - {\vec{v}}_{1} ) ] {\vec{n}}_{1} \qquad ( 9 )$$

$${\vec{{b}^{′}}}_{0 , 1 , 2} = {\vec{b}}_{0 , 1 , 2} + [ {\vec{n}}_{2} \cdot ( {\vec{b}}_{0 , 1 , 2} - {\vec{v}}_{2} ) ] {\vec{n}}_{2} \qquad ( 10 )$$

$${\vec{{b}^{′}}}_{0 , 0 , 3} = {\vec{b}}_{0 , 0 , 3} \qquad ( 11 )$$

$${\vec{{b}^{′}}}_{1 , 1 , 1} = {\vec{b}}_{1 , 1 , 1} + 1.5 [ \{ {\vec{n}}_{0} \cdot ( {\vec{b}}_{2 , 1 , 0} + {\vec{b}}_{1 , 2 , 0} - 2 \vec{v} ) \} {\vec{n}}_{0} + \{ {\vec{n}}_{1} \cdot ( {\vec{b}}_{1 , 2 , 0} + {\vec{b}}_{0 , 2 , 1} - 2 {\vec{v}}_{1} ) \} {\vec{n}}_{1} + \{ {\vec{n}}_{2} \cdot ( {\vec{b}}_{0 , 1 , 2} + {\vec{b}}_{1 , 0 , 2} - 2 {\vec{v}}_{2} ) \} {\vec{n}}_{2} ] / 6 \qquad ( 12 )$$

As shown in FIG. 3, the normal vectors n₀, n₁, and n₂ are the normal vectors at vertices A, B, and C, respectively.

Equations (3) to (11) are equations for moving each of the control point bi such that a line extending from the vertex to the nearest control point bi is perpendicular to the vertex normal vector. However, control points b_{3,0,0}, b_{0,3,0}, and b_{0,0,3} are vertices. Therefore, the positions of the control points b_{3,0,0}, b_{0,3,0}, and b_{0,0,3} are not changed.

Equation (12) is an equation to ensure that the displacement of the control point b_{1,1,1} is larger than that of other control points bij,k.

As shown in FIG. 2, in step S40, the CPU 21 calculates the collision position where the radar wave collides with the Bezier surface based on the position of the control points b′i moved in step S30 and the collision position calculated in step S10, and terminates the collision position correction processing.

The collision position where the radar wave collides with the target polygon and the position of the each control point are each represented by barycentric coordinates, which are relative positions within the polygon. Each of the barycentric coordinates is represented by a three-component vector U=(u, v, w). The barycentric coordinates indicate how close any point on a triangle is to each of the vertices of the triangle. The sum of u, v, and w is always 1. The position vector p indicating the position of any point on triangle ABC is expressed by Equation (13). In equation (13), the order of u, v, w is w, u, v from left to right for ease of calculation.

$$[ Math 3 ]$$

$$\vec{p} = w \vec{A} + u \vec{B} + v \vec{C} \qquad ( 13 )$$

A Bezier surface is expressed by Equations (14) and (15).

n in equation (14) is the degree of the Bezier surface. The vector U is a vector of the collision position. B(u) is the Bernstein coefficient. Each of the i, j, and k is an identification number of the control point. bn(U) is the position on the Bezier surface corresponding to the collision position. b′ᵢ is the position of the control point b′ᵢ moved in S30.

$$[ Math 4 ]$$

$${B}_{\vec{ι}}^{n} = \frac{n !}{i ! j ! k !} {u}^{i} {v}^{j} {w}^{k} , \vec{ι} = ( i , j , k ) , \vert \vec{ι} \vert = i + j + k = n , i , j , k \geq 0 \qquad ( 14 )$$

$${\vec{b}}^{n} ( \vec{u} ) = {\sum }_{\vert \vec{ι} \vert = n} \vec{{b}_{\vec{ι}}^{′}} {B}_{\vec{ι}}^{n} ( \vec{u} ) \qquad ( 15 )$$

In this embodiment, the degree of the Bezier surface (i.e., n) is 3. Therefore, the CPU 21 calculates the collision position b³ (U) where the radar wave collides with the Bezier surface using equations (16) and (17).

$$[ Math . 5 ]$$

$${B}_{\vec{ι}}^{3} = \frac{6}{i ! j ! k !} {u}^{i} {v}^{j} {w}^{k} , \vec{ι} = ( i , j , k ) , \vert \vec{ι} \vert = i + j + k = 3 , i , j , k \geq 0 \qquad ( 16 )$$

$${\vec{b}}^{3} ( \vec{u} ) = {\sum }_{\vert \vec{ι} \vert = 3} \vec{{b}_{\vec{ι}}^{′}} {B}_{\vec{ι}}^{3} ( \vec{u} ) \qquad ( 17 )$$

The CPU21 performs, in the radar simulation, collision position correction process each time the radar wave is generated, calculating the collision position where the radar wave collides with the Bezier surface.

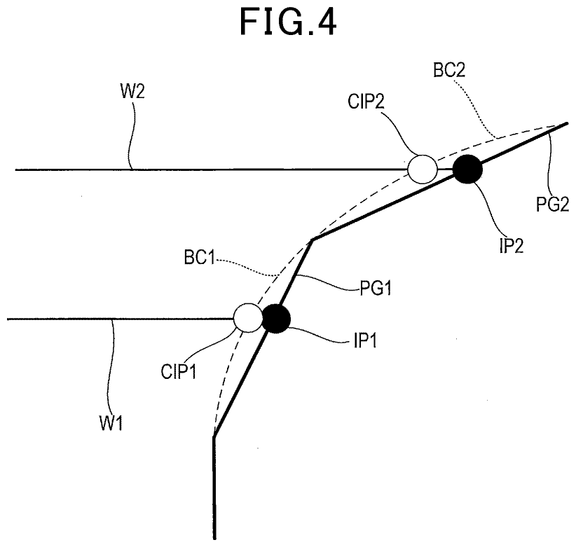

As shown in FIG. 4, the CPU21, in the radar simulation, may calculate, for example, the collision point IP1 where the radar wave W1 collides with the polygon PG1. The CPU21, in the radar simulation, then calculates the position corresponding to the collision point IP1 on the Bezier surface BC1 of the polygon PG1 as the corrected collision point CIP1.

Similarly, the CPU 21 may calculate, in the radar simulation, for example, the collision point IP2 where the radar wave W2 collides with the polygon PG2. The CPU 21, in the radar simulation, then calculates the position corresponding to the collision point IP2 on the Bezier surface BC2 of the polygon PG2 as the corrected collision point CIP2.

The CPU 21, in the radar simulation, calculates the timing at which the radar device receives the radar wave and the received power, based on the radar waves reflected at each of the corrected collision points CIP1 and CIP2.

The radar simulator 1 is configured to identify, as the target polygon, one of multiple polygons whose vertices are a set of three-dimensional coordinate points representing the three-dimensional shape of an object surface, where the simulated radar wave collides with that polygon.

The radar simulator 1 is configured to calculate the collision point where the radar wave collides with the Bezier surface based on the Bezier surface calculated by performing surface interpolation on the plane of the target polygon.

The radar simulator 1 can improve simulation accuracy by minimizing the difference between the position where the radar wave collides with the actual object and the position where the radar wave collides with the object reproduced in the simulation.

In the above-described embodiment, the radar simulator 1 corresponds to a simulation device, the radar wave corresponds to a wave (electromagnetic wave), S10 corresponds to processing as a polygon identification unit, the Bezier surface corresponds to a target surface, and S20 to S40 correspond to processing as a collision position correction unit.

The present disclosure has been described with reference to one embodiment, but the disclosure is not limited to the above embodiment and may be implemented in various modifications.

### Modified Embodiment 1

The above embodiment illustrates a configuration where the radar waves are formed as waves (electromagnetic waves) through simulation. However, the waves may be formed as electromagnetic waves, ultrasonic waves, or light.

### Modified Embodiment 2

The above embodiment showed a configuration where the three-dimensional shape of an object surface is reproduced using triangular polygons, but the three-dimensional shape of an object surface may also be reproduced using polygons other than triangles.

### Modified Embodiment 3

The above embodiment showed a configuration where the Bezier surfaces are calculated by performing surface interpolation. However, the method for converting planar polygons into surfaces is not limited to the method of calculating Bezier surfaces and may be any method.

### Modified Embodiment 4

The above embodiment described a configuration where the position on the Bezier surface corresponding to the collision point on the triangular polygon is calculated as the point where the radar wave collided with the Bezier surface. However, it may also calculate the position of the intersection between the target surface calculated by performing surface interpolation on the plane of the target polygon and the propagation path of the radar wave formed by simulation as the position of the collision point where the radar wave collided with the target surface.

The control unit 15 and its method described in this disclosure may be implemented by a dedicated computer provided by configuring a processor and memory programmed to execute one or more functions embodied by a computer program. Alternatively, the control unit 15 and its method described herein may be implemented by a dedicated computer provided by configuring a processor with one or more dedicated hardware logic circuits. Or the control unit 15 and its method described herein may be implemented by one or more dedicated computers configured by a combination of a processor programmed to execute one or more functions and one or more hardware logic circuits. Furthermore, the computer program may be stored on a computer-readable, non-transitory tangible medium as instructions executable by a computer. The method for implementing the functions of each part included in the control unit 15 need not necessarily include software; all the functions may be implemented using one or more hardware components.

Multiple functions possessed by one component in the above embodiment may be realized by multiple components, or one function possessed by one component may be realized by multiple components. Furthermore, multiple functions possessed by multiple components may be realized by one component, or one function realized by multiple components may be realized by one component. Additionally, part of the configuration of the above embodiment may be omitted. Furthermore, at least a portion of the configuration of the above embodiment may be added to or substituted for the configuration of another above embodiment.

In addition to the radar simulator 1 described above, the present disclosure may be embodied in various forms, such as a system comprising the radar simulator 1 as a component, a program for causing a computer to function as the radar simulator 1, a non-transitory physical storage medium such as a semiconductor memory recording this program, and a simulation method.

What is claimed is:

1. A Simulation device comprising:
a polygon identification unit configured to identify a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface,
a collision position correction unit configured to calculate a collision point where the wave collides with based on a target surface, the target surface is a surface calculated by performing a surface interpolation on the plane of the target polygon.

2. The simulation device according to claim 1, wherein
the collision position correction unit is configured to:
set control points on the plane of the target polygon formed by connecting three or more of vertices with straight lines;
move the control points such that a line extending from the vertex to the nearest control point is perpendicular to a vertex normal, which is a normal vector at the vertex; and
perform the surface interpolation on the plane of the target polygon based on the moved control points.

3. A simulation method performed by a simulation device comprising:
identifying a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface,
calculating a collision point where the wave collides with based on a target surface, the target surface is a surface calculated by performing a surface interpolation on the plane of the target polygon.

4. A non-transitory computer-readable storage medium storing a simulation program configured to cause a computer to operate as:
a polygon identification unit configured to identify a target polygon among multiple polygons, the target polygon being a polygon with which a wave formed by simulation collides, each of the multiple polygons having vertices, each of the vertices being a point of a three-dimensional coordinate point cloud representing a three-dimensional shape of an object surface,
a collision position correction unit configured to calculate a collision point where the wave collides with based on a target surface, the target surface is a surface calculated by performing a surface interpolation on the plane of the target polygon.
